(19) United States
(12) Patent Application Publication
(10) Pub. No.: US 2007/0134415 A1
(43) Pub. Date: Jun. 14, 2007

(54) Oxidation Treatment Apparatus and Method

(76) Inventors: Ki-Hyun Hwang, Seongnam-si (KR); U-In Chung, Seoul (KR); Yu-Gyun Shin, Seongnam-si (KR); Jae-Young Ahn, Seongnam-si (KR); Jin-Gyun Kim, Yongin-si (KR)

Correspondence Address: Frank Chau, Esq.;F. CHAU & ASSOCIATES, LLC, 130 Woodbury Road, Woodbury, NY, 11797, US

(21) Appl. No.: 11/563,980

(22) Filed: Nov. 28, 2006

(30) Foreign Application Priority Data
Dec. 1, 2005 (KR) 2005-116482

(51) Int. Cl. C23C 16/00; B05D 3/04; B05D 7/00; B05D 1/02

(52) U.S. Cl. 427/248.1; 427/421.1; 427/377; 118/719

(57) ABSTRACT

An oxidation treatment apparatus for oxidizing a surface of a substrate includes a process chamber for performing a process, a boat supporting the substrate and disposed in the process chamber during the process and a first ozone supply unit supplying ozone to the process chamber. The first ozone supply unit includes an ozone generator disposed at an exterior of the process chamber and an ozone spray nozzle disposed in the process chamber to spray the ozone supplied from the ozone generator into the process chamber.

### CROSS-REFERENCE TO RELATED APPLICATION

This application claims priority from Korean Patent Application No. 10-2005-116482, filed on Dec. 1, 2005, the disclosure of which is hereby incorporated by reference herein in its entirety.

### BACKGROUND OF THE INVENTION

1. Technical Field

The present disclosure relates to an apparatus and method for manufacturing a semiconductor device, and more particularly, to an oxidation treatment apparatus and method for a semiconductor substrate.

2. Description of the Related Art

Generally, a variety of processes are performed on a semiconductor wafer to manufacture a semiconductor device. Among these processes is an oxidation process performed to form an oxidation layer on the semiconductor wafer by supplying oxygen to the semiconductor wafer. A conventional oxidation process is generally performed by disposing a boat to a load a plurality of wafers into a process chamber and then injecting reaction gases including oxygen (O₂) and hydrogen (H₂) into the process chamber. However, with the above conventional oxidation process, the hydrogen (H) which is implanted in the oxide layer may deteriorate the reliability of the oxidation layer. Particularly, when the oxidation process is performed to form a tunnel oxidation layer in a flash memory, the reliability of the tunnel oxidation layer may be significantly deteriorated even when a small amount of the hydrogen (H) is implanted in the tunnel oxidation layer.

In addition, when the conventional oxidation process is performed by supplying the hydrogen (H₂) and the oxygen (O₂), the process chamber maintains a high temperature to generate oxygen (O) by the reaction of the hydrogen (H₂) and the oxygen (O₂). As a result, it may be difficult to form a thin oxidation layer of about 20 to about 30 angstroms (Å).

Furthermore, due to residual hydrocarbons on a surface of the wafer, it may be difficult to form an oxidation layer having improved quality on the wafer through the oxidation process.

Also, with the above-mentioned conventional process, a variety of metal structures are generally provided in the process chamber. While the oxidation process is performed, a variety of metal particles such as sodium particles, iron particles, and manganese particles are generated from the metal structures. The metal particles adhere to the wafer, which may in turn cause process failure.

Thus, there is a need for an oxidation treatment apparatus and method that can form a an oxidation layer having improved quality in comparison to the conventional art on a semiconductor substrate.

### SUMMARY OF THE INVENTION

The exemplary embodiments of the present invention provide an oxidation treatment apparatus and method that can form an oxidation layer having improved quality on a semiconductor substrate.

The exemplary embodiments of present invention also provide an oxidation treatment apparatus and method that can minimize the implantation of the hydrogen in an oxidation layer during an oxidation process for forming the oxidation layer on a wafer.

The exemplary embodiments of the present invention also provide an oxidation treatment apparatus and method that can form an oxidation layer having improved quality on a semiconductor substrate by removing metal particles from a process chamber during an oxidation process.

The exemplary embodiments of the present invention also provide an oxidation treatment apparatus and method that can form an oxidation layer having improved quality on a semiconductor substrate by removing hydrocarbon from the semiconductor substrate before the oxidation process is performed.

In accordance with an exemplary embodiment of the present invention, an oxidation treatment apparatus for oxidizing a surface of a substrate is provided. The apparatus includes a process chamber for performing a process, a boat supporting the substrate and disposed in the process chamber during the process and a first ozone supply unit supply ozone to the process chamber. The first ozone supply unit includes an ozone generator disposed at an exterior of the process chamber and an ozone spray nozzle disposed in the process chamber to spray the ozone supplied from the ozone generator into the process chamber. A plurality of substrates may be further vertically stacked in the boat and the ozone spray nozzle may be vertically arranged and provided with a plurality of spray holes arranged in a vertical direction along a length of the ozone spray nozzle.

In some exemplary embodiments, the first ozone supply unit may further include a cooling member for cooling the ozone supplied to the ozone spray nozzle. The cooling member may include a cooling tube along which coolant flows. The cooling tube is disposed to enclose the ozone spray nozzle. A separation plate for dividing a space of the cooling tube into first and second compartments may be disposed in the cooling tube so that the coolant flows upward along the first compartment and then flows downward along the second compartment. The ozone spray nozzle may be disposed in the cooling tube, the cooling tube may be provided with holes corresponding to the spray holes formed on the ozone spray nozzle and the first ozone supply unit may further include a plurality of spray tubes inserted into the spray holes of the ozone spray nozzle and the holes of the cooling tube.

In further exemplary embodiments, the oxidation treatment apparatus may further include a removal gas supply tube connected to an ozone supply tube connecting the ozone spray nozzle to the ozone generator to supply removal gas, which can react with metal particles in the process chamber to remove the metal particles, into the process chamber. The removal gas may include at least one of trichloroethane (C₂H₃Cl₃), trichloroethylene (C₂HCl₃) and hydrogen chloride (HCl).

In other exemplary embodiments, the oxidation treatment apparatus may further include a load-lock chamber disposed below the process chamber to provide a space where the wafer is loaded in the boat, a boat driving unit for moving the boat between the process chamber and the load-lock chamber and a second ozone supply unit supplying ozone to the load-lock chamber to form a passivation layer on the substrate loaded in the boat disposed in the load-lock chamber. The second ozone supply unit may include an ozone generator disposed at an exterior of the load-lock chamber and an ozone spray nozzle disposed in the load-lock chamber to spray the ozone supplied from the ozone generator into the load-lock chamber. The ozone spray nozzle of the second ozone supply unit may be vertically arranged and provided with a plurality of spray holes arranged in a vertical direction along a length of the ozone spray nozzle.

In still other exemplary embodiments, the oxidation treatment apparatus may further include a heating member for heating an interior of the load-lock chamber to a process temperature and the second ozone supply unit may further include a cooling member for cooling the ozone supplied to the ozone spray nozzle disposed in the load-lock chamber.

In accordance with an exemplary embodiment of the present invention, an oxidation treatment method for oxidizing a surface of a substrate is provided. The method includes generating ozone at an exterior of a process chamber and supplying the ozone into the process chamber to oxidize the surface of the substrate.

In some exemplary embodiments, the ozone may be sprayed toward the substrate through an ozone spray nozzle disposed in the process chamber and the ozone in the ozone spray nozzle is cooled by coolant.

In other exemplary embodiments, the oxidation treatment method may further include supplying a removal gas for removing residual metal in the process chamber during an oxidation process which supplies ozone into the process chamber. A volume of the removal gas supplied into the process chamber may be within the range of about 1/10 to about 1/10000 of that of the ozone gas supplied into the process chamber. The removal gas may include at least one of trichloroethane (C₂H₃Cl₃), trichloroethylene (C₂HCl₃) and hydrogen chloride (HCl).

In still other exemplary embodiments, the oxidation treatment method may further include forming a passivation layer on the substrate loaded in the boat disposed in a load-lock chamber by supplying ozone into a load-lock chamber before the process is performed in the process chamber. The oxidation treatment method may further include heating the substrate in the load-lock chamber while the passivation layer is formed on the substrate by ozone supplied into the load-lock chamber.

### BRIEF DESCRIPTION OF THE DRAWINGS

Exemplary embodiments of the present invention can be understood in more detail from the following description taken in conjunction with the accompanying drawings in which:

FIG. 1 is a schematic view of an oxidation treatment apparatus according to an exemplary embodiment of the present invention;

FIG. 2 is a partly broken perspective view illustrating an internal structure of the first ozone supply unit of FIG. 1;

FIG. 3 is a longitudinal sectional view of the first ozone supply unit of FIG. 1;

FIG. 4 is a sectional view taken along line I-I of FIG. 3, illustrating a first ozone spraying nozzle and a cooling member;

FIG. 5 is a view of a lifetime of ozone according to a temperature;

FIG. 6 is a perspective view of a separation plate of FIG. 3;

FIG. 7 is a view illustrating flow paths of coolant and ozone in an ozone spraying nozzle and a cooling tube;

FIG. 8 is a schematic view of an oxidation treatment apparatus according to an exemplary embodiment of the present invention;

FIG. 9 is a schematic view of an oxidation treatment apparatus according to an exemplary embodiment of the present invention;

FIG. 10 is a schematic view of a second ozone supply unit of FIG. 9; and

FIG. 11 is a schematic view of an oxidation treatment apparatus according to an exemplary embodiment of the present invention.

### DETAILED DESCRIPTION OF THE EXEMPLARY EMBODIMENTS

Reference will now be made in detail to the exemplary embodiments of the present invention, examples of which are illustrated in the accompanying drawings. However, the present invention is not limited to the exemplary embodiments illustrated herein after.

The exemplary embodiments of the present invention provide an apparatus for an oxidation treatment of a substrate such as, for example, a semiconductor wafer. For example, the apparatus 10 may be used for a process for forming a tunnel oxidation layer using oxygen in a flash memory manufacturing process. However, the apparatus 10 may be applied to a variety of other processes for forming, for example, a gate oxidation layer by supplying oxygen to the wafer W.

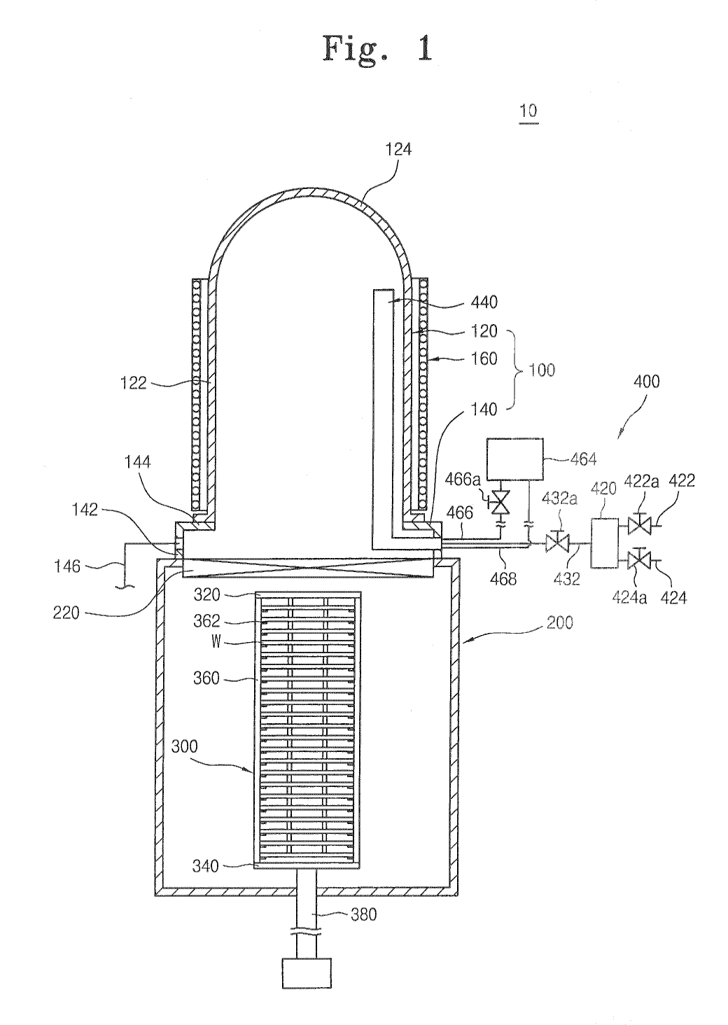

FIG. 1 is a schematic view of an oxidation treatment apparatus according to an exemplary embodiment of the present invention. Referring to FIG. 1, an oxidation treatment apparatus 10 includes a process chamber 100, a load-lock chamber 200, a boat 300, and a first ozone supply unit 400. The boat 300 supports a plurality of wafers W during the process. The load-lock chamber 200 maintains a predetermined internal vacuum pressure. In a state where the boat 300 is disposed in the load-lock chamber 200, the wafers W are loaded in and unloaded from the boat 300 by a transfer robot. The transfer robot is disposed at an external side of the chamber 200. The load-lock chamber 200 is provided at a wall with an opening through which an arm of the transfer robot comes in and goes out. The opening is opened and closed by a door. The process chamber 100 is disposed above the load-lock chamber 200.

The process chamber 100 provides a space in which a diffusion process for the wafers W is performed. The boat 300 moves vertically between the process chamber 100 and the load-lock chamber 200 by a boat driving unit 380. An opening/closing member 220 is installed between the load-lock chamber 200 and the process chamber 100 to open and close a passage along which the boat 300 moves. When the loading of the wafers W in the boat 300 is completed, the boat 300 moves from the load-lock chamber 200 to the process chamber 100.

The boat 300 includes an upper plate 320, a lower plate 340 and a plurality of vertical supports 360. The upper and lower plates 320 and 340 are disk-shaped and face each other in a vertical direction. The vertical supports 360 are fixedly disposed between the upper and lower plates 320 and 340. For example, three or four vertical supports 360 may be provided. The vertical supports 360 are rod-shaped extending vertically. Ledges 362 on which edges of the wafers W are supported are formed on the vertical supports 360. The ledges 362 are spaced apart from each other by a predetermined distance in the vertical direction. That is, each wafer W is supported by three or four ledges 362 disposed on an identical plan. For example, 25-50 ledges 362 are formed on each vertical support 360 so that 25-50 wafers W can be simultaneously loaded in the boat 300.

The process chamber 100 includes a process tube 120, a flange 104, and a heating member 160. The flange 140 is disposed on a top surface of the load-lock chamber 200. The flange 140 includes a cylindrical sidewall 142 and an upper wall 144 having a central opening. The lower portion of the flange 140 is opened. The sidewall 142 of the flange 140 is provided with an outlet coupled to an exhaust tube 146 and an inlet which the first ozone supply unit 400 is inserted. The inlet and outlet are arranged to be opposite to each other. The process tube 120 is installed on the upper wall 144 of the flange 140. A sealing member such as an O-ring is interposed between the process tube 120 and the flange 140. The process tube 120 includes a hollowed cylindrical sidewall 122 and an upper wall 124 formed on a dome-shape. The lower portion of the process tube 120 is opened. During the process, the boat 300 is disposed in the process tube 120. The heating member 160 is installed on an outer side of the sidewall 122 of the process tube 120 to heat the interior of the process tube 120 to a process temperature. For example, the heating member 160 may be a heating wire wound around the process tube 120.

A purge gas supply tube for supplying inert gas such as nitrogen gas may be connected to the process chamber 100 and the load-lock chamber 200 to purge the interiors of the process chamber 100 and the load-lock chamber 200.

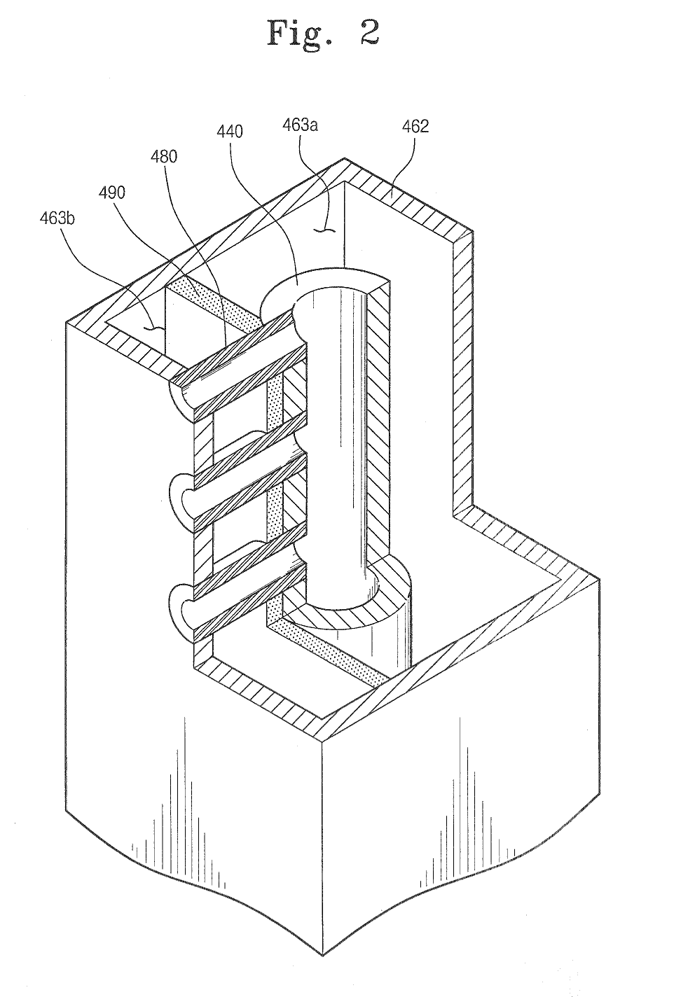

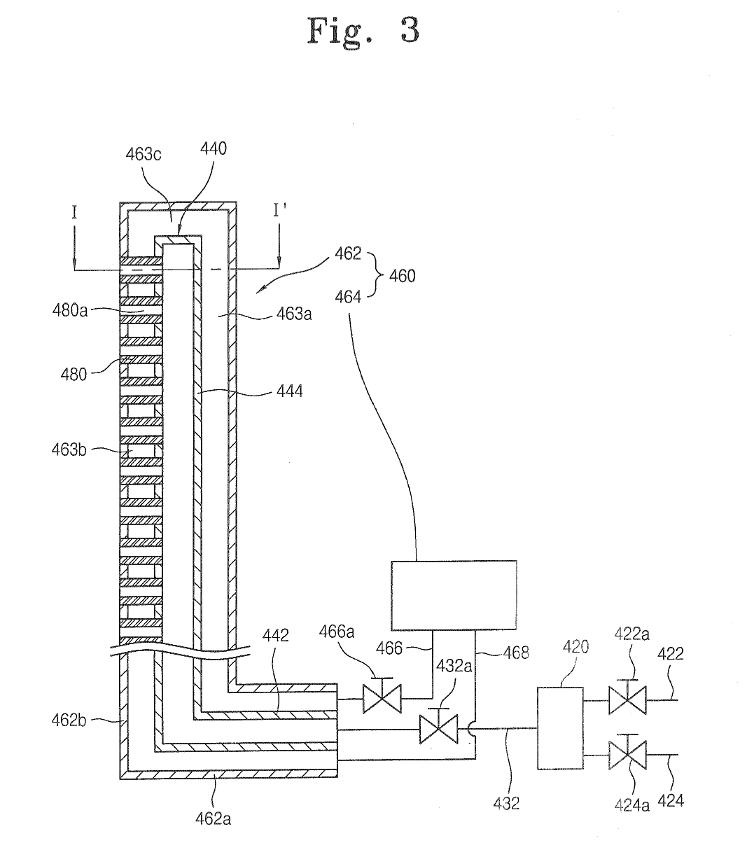

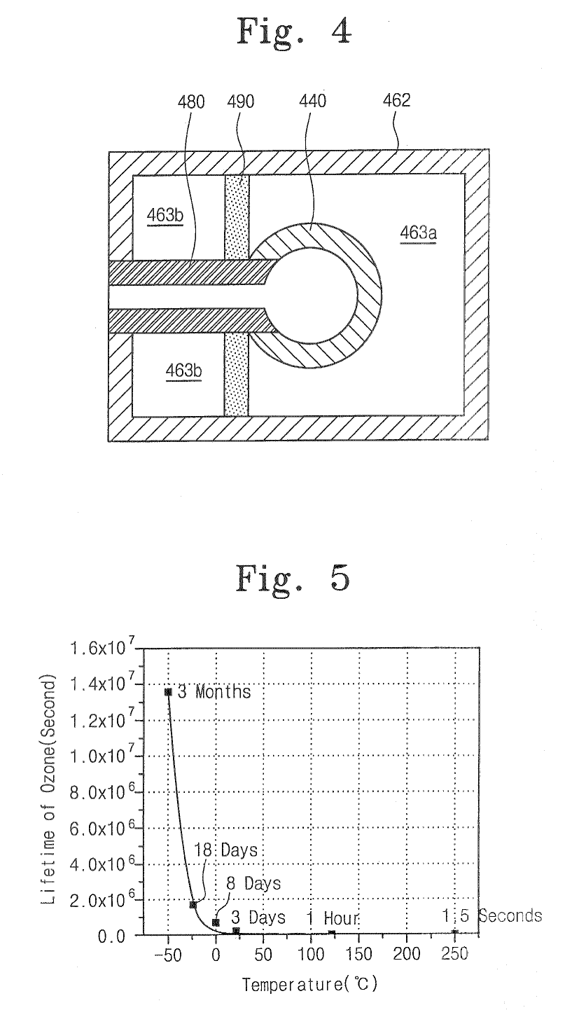

The first ozone supply unit 400 supplies ozone into the process chamber 100. FIG. 2 is a partly broken perspective view illustrating an internal structure of the first ozone supply unit of FIG. 1, FIG. 3 is a longitudinal sectional view of the first ozone supply unit of FIG. 1, and FIG. 4 is a sectional view taken along line I-I of FIG. 3. Referring to FIGS. 2 through 4, the first ozone supply unit 400 includes an ozone generator 420, an ozone supply tube 432, an ozone spray nozzle 440, and a cooling member 460. The ozone generator 432 generating ozone is disposed at an exterior of the process chamber 100. A reaction gas supply tube is connected to the ozone generator 420 to supply reaction gas used to generate the ozone to the ozone generator 420. For example, the reaction gas supply tube includes an oxygen gas supply tube 422 for supplying oxygen and a hydrogen gas supply tube 424 for supplying hydrogen. The ozone generated from the ozone generator 420 is directed to the ozone spray nozzle 440 via the ozone supply tube 432. Valves 4222a, 424a and 432a are respectively installed on the oxygen supply tube 422, the hydrogen supply tube 424 and the ozone supply tube 432 to open and close the passages thereof.

The ozone spray nozzle 440 is formed in a rod shape having a horizontal portion 442 and a vertical portion 444. The horizontal portion 442 is connected to the ozone supply tube 432 and inserted in the process chamber 100 through the inlet formed on the flange 140. The vertical portion 444 extends vertically from an end of the horizontal portion 442. The vertical portion 444 extends to close or above the uppermost one of the wafers W loaded in the boat 300. A plurality of spray holes are formed on the vertical portion 444 and arranged in a longitudinal direction of the vertical portion 444. The spray holes are spaced apart from each other at identical intervals. Alternatively, intervals between the spray holes may be reduced as they go upward.

According to the exemplary embodiments of the present invention, the ozone is not generated in the process chamber by supplying oxygen (O₂) and hydrogen (H₂) or inert gases containing the oxygen and hydrogen gases into the process chamber 100 but rather the ozone is generated at the exterior of the process chamber 100 and is directly supplied into the process chamber 100. Therefore, the oxidation process is performed in the process chamber 100 without hydrogen. Even when the hydrogen is supplied into the process chamber 100 due to other purposes rather than the generation of the ozone, the oxidation process is performed in the process chamber 100 having a small amount of hydrogen. Therefore, in the diffusion process, no hydrogen or a small amount of hydrogen is implanted in the oxidation layer and thus the reliability of the oxidation layer is not deteriorated.

In addition, as the ozone is generated at the exterior of the process chamber 100 and is then supplied into the process chamber 100, the process chamber 100 may be at a relatively low temperature less than, for example, about 800 Celsius (° C.). Therefore, an oxidation layer having a relatively thin thickness of about 10 to about 60 anstroms (Å) can be formed.

Generally, as shown in FIG. 5, the lifetime of the ozone is very short at a high temperature. As the interior of the process chamber 100 is heated to a high temperature by the heating member 160, the ozone may be decomposed into oxygen (O₂) before the ozone is sprayed toward the wafer W through the ozone spray nozzle 440. Therefore, the amount of the ozone decreases as it goes upward in the vertical portion 444 of the ozone spray nozzle 440. Therefore, the amount of ozone sprayed to the wafers disposed at a higher level is relatively small. Therefore, a thickness uniformity of the oxidation layers of the wafers W is deteriorated.

The cooling member 460 cools the ozone spray nozzle 440 to increase the lifetime of the ozone in the ozone spray nozzle 440. Referring again to FIGS. 2 through 4, the cooling member 460 includes a cooling tube 462, a temperature control portion 464, a coolant supply tube 466, a coolant recovery tube 468, and a separation plate 469. The cooling tube 462 is disposed to fully enclose the ozone spray nozzle 440. Therefore, the cooling tube 462 has a horizontal portion 462a and a vertical portion 462b. The cross-section of the cooling tube 462 is rectangular-shaped. The cooling tube 462 is provided with a plurality of holes corresponding to the spray holes formed on the ozone spray nozzle 440. Spray tubes 480 are inserted in the spray holes formed on the ozone spray nozzle 440 and the holes formed on the cooling tubes 462. The ozone directed to the ozone spray nozzle 440 is sprayed toward the wafers W through the spray tubes 480. The separation plate 469 is installed in the cooling tube 462 to divide a space of the cooling tube 462 into the first and second compartments 463a and 463b.

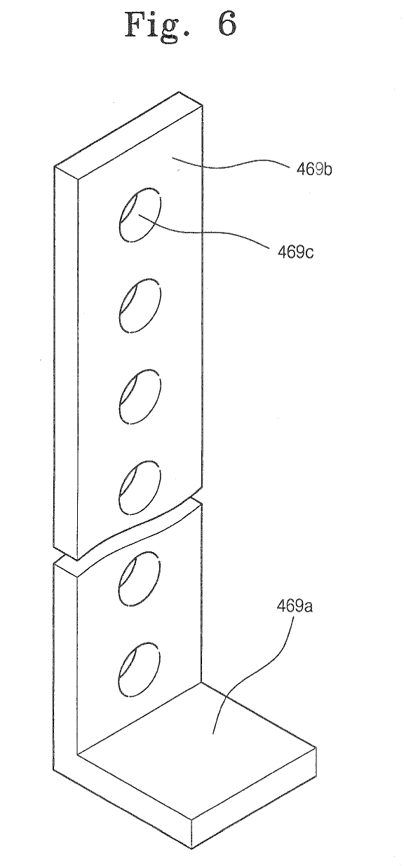

FIG. 6 shows the separation plate 469. Referring to FIG. 6, the separation plate 469 has a horizontal portion 469a and a vertical portion 469b. The horizontal portion 469a of the separation plate 469 is disposed in the horizontal portion 462a of the cooling tube 462. The vertical portion 469b of the separation plate 469 is disposed in the vertical portion 462b of the cooling tube 462. The vertical portion 426b of the separation plate 469 extends vertically from an end of the horizontal portion 469a of the separation plate 469. By the above-described structure, the first compartment 463a is placed in front of the separation plate 469 and the second compartment 463b is placed in the rear of the separation plate 469. To allow the first compartment 463a to communicate with the second compartment 463b at an upper end area 463c of the cooling tube 462, the vertical portion 469b of the separation plate 469 extends upward to be spaced apart from an upper end of the cooling tuber 462. The separation plate 469 is provided with through holes 469c through which the spray tubes 480 are inserted.

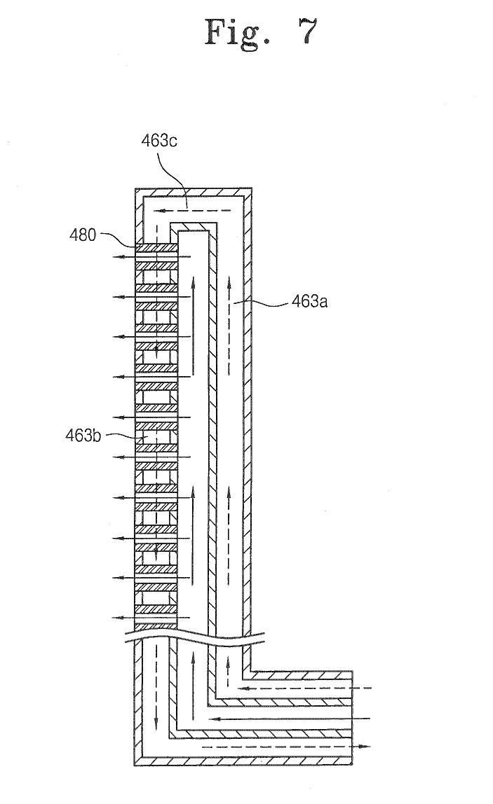

The coolant supply tube 466 is connected to the first compartment 463a of the cooling tube 462 and the coolant recovery tube 468 is connected to the second compartment 463b. A flow control valve 466a for controlling a flow rate of the coolant is installed on the coolant supply tube 466. A solenoid valve that can be electrically controlled may be used as the flow control valve 466a. The coolant whose temperature is controlled by the temperature control portion 464 is supplied to the first compartment 463a through the coolant supply tube 466. As shown in FIG. 7, the coolant flows from a bottom to a top of the first compartment 462a and flows into the second compartment 462b through the upper end area 462c. Then, the coolant flows from a top to a bottom of the second compartment 462b and is returned to the temperature control portion 464 through the coolant recovery tube 468. In FIG. 7, the solid line indicates a flow path of the ozone and the dotted line denotes a flow path of the coolant. By the coolant flowing from the first compartment 462a to the second compartment 462b, the ozone in the ozone spray nozzle 440 can be maintained at a relatively low temperature.

For example, inert gas such as, for example, nitrogen gas may be used as the coolant. The nitrogen gas may be supplied to the cooling tube 462 at a normal temperature. Alternatively, the temperature of the nitrogen gas may be adjusted by the temperature control portion 464 to a temperature appropriate for the cooling operation and then supplied to the cooling tube 462. Alternatively, cooling water may be used as the coolant.

According to the exemplary embodiments of the present invention, as the ozone in the ozone spray nozzle 440 is cooled by the coolant, the lifetime of the ozone in the ozone spray nozzle 440 increases. Therefore, as the ozone is uniformly sprayed to all of the wafers W loaded in the boat 300, the thickness distribution of the oxidation layers of the wafers W is uniform.

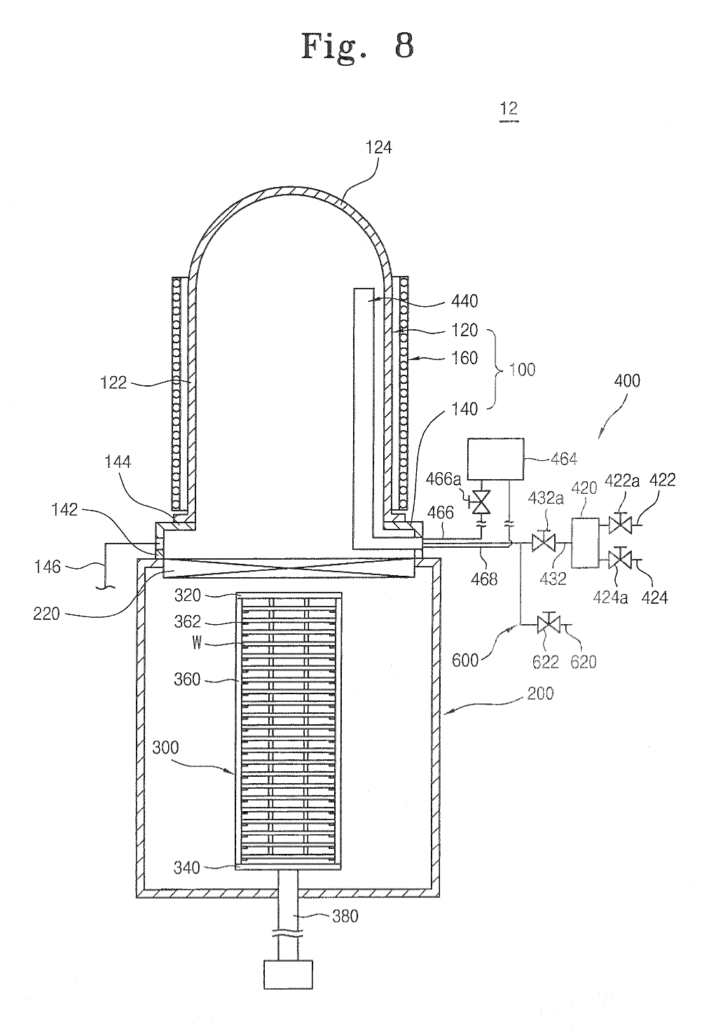

FIG. 8 is a schematic view of an oxidation treatment apparatus according to an exemplary embodiment of the present invention. According to an oxidation treatment apparatus 12 of FIG. 8, a removal gas supply member 600 for supplying removal gas into the process chamber 100 is added to the oxidation treatment apparatus 10 of FIG. 1. During the process, metal particles are generated in the process chamber 100. When the metal particles are implanted in the oxidation layer, the reliability of the oxidation layer is deteriorated. The metal particles may be generated from the metal structures provided in the process chamber 100.

The removal gas reacts with the metal particles in the process chamber 100 during the process of that the metal particles can be exhausted out of the process chamber 100. For example, the metal particles generated in the process chamber 100 may be sodium (Na), iron (Fe) or manganese (Mn). Trichloroethane (C₂H₃Cl₃), trichloroethylene (C₂HCl₃), and/or hydrogen chloride (HCl) may be used as the removal gas. It is preferably to supply a proper amount of the removal gas to the process chamber 100. When an amount of the removal gas supplied to the process chamber 100 is too small, the metal particles may not be sufficiently removed. When the amount of the removal gas supplied to the process chamber 100 is too large, a large amount of the hydrogen generated from the removal gas may be implanted in the oxidation layer. For example, a volume of the removal gas supplied into the process chamber 100 may be in the range of about 1/10 to about 1/10000 of that of the oxidation gas supplied into the process chamber 100.

The removal gas supply member 600 includes a removal gas supply tube 620 connected to the ozone supply tube 432. A flow rate control valve 622 is installed on the removal gas supply tube 620 to control the flow rate of the removal gas flowing along the removal gas supply tube 620. Therefore, the removal gas can be supplied into the process chamber 100 together with the ozone through the ozone spray nozzle 440. Alternatively, the removal gas supply member 600 may include a removal gas spray nozzle and a removal gas supply tube connected to the removal gas spray nozzle. In this case, the removal gas and the ozone are separately supplied into the process chamber 100.

When the ozone is generated by supplying the oxygen (O₂) and the hydrogen (H₂) into the process chamber 100 and the removal gas such as the hydrogen chloride (HCl) is supplied together with the oxygen and the hydrogen, the parts in the process chamber may corrode due to the reaction between the water molecules generated by the reaction of the oxygen and the hydrogen and the hydrogen chloride gas. However, according to the exemplary embodiments of the present invention, as the ozone is generated at the exterior of the process chamber and is then supplied into the process chamber 100, the above difficulties can be avoided.

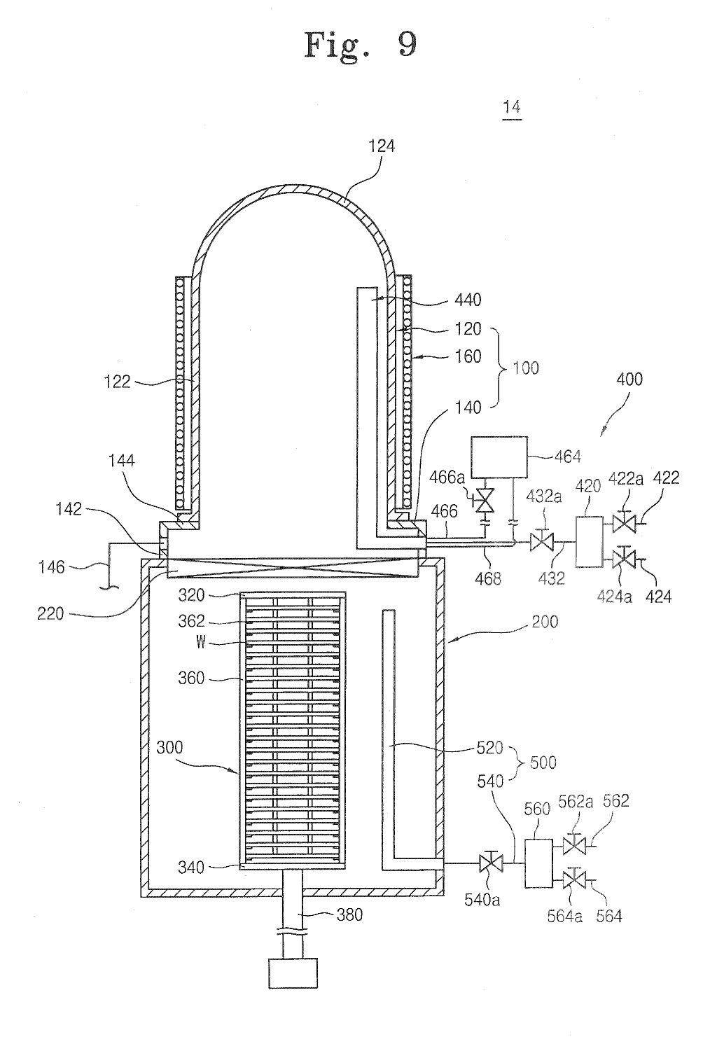

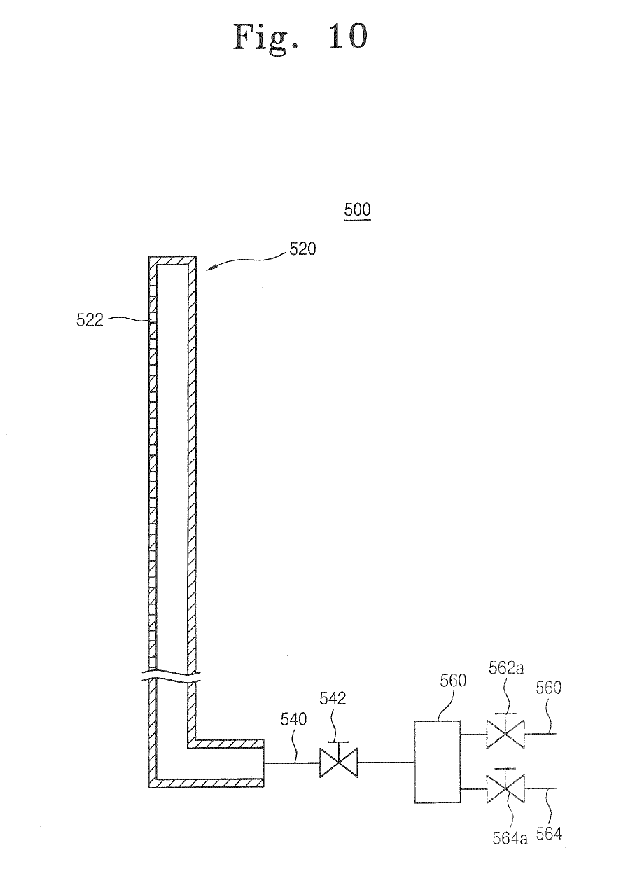

FIG. 9 is a schematic view of an oxidation treatment apparatus according to another exemplary embodiment of the present invention. According to an oxidation treatment apparatus 14 of FIG. 9, a second ozone supply unit 500 installed on the load-lock chamber 200 is added to the oxidation treatment apparatus 10 of FIG. 1. The second ozone supply unit 500 supplies the ozone to the load-lock chamber 200 before the boat 300 moves into the process chamber 100. The ozone supplied to the load-lock chamber 200 removes hydrocarbon from the surfaces of the wafers W and forms a passivation layer on each of the wafers W loaded in the boat 300 disposed in the load-lock chamber 200. FIG. 10 is a schematic view of the second ozone supply unit of FIG. 9. Referring to FIG. 10, the second ozone supply unit 500 includes an ozone spray nozzle 520, an ozone supply tube 540, and an ozone generator 560. The ozone generator 560 is disposed at an exterior of the load-lock chamber 200. A reaction gas supply tube for supplying reaction gas to the ozone generator 460 is connected to the ozone generator 560. The reaction gas supply tube includes an oxygen gas supply tube 562 for supplying oxygen gas and a hydrogen gas supply tube 564 for supplying hydrogen gas. Valves 562a and 564a are respectively installed on the oxygen and hydrogen gas supply tubes 562 and 564.

The ozone generated from the ozone generator 560 is directed to the ozone spray nozzle 520 through the ozone supply tube 540. A flow control valve 542 for controlling the flow rate of the ozone is installed on the ozone supply tube 540. The ozone spray nozzle 520 is disposed in the load-lock chamber 200.

The ozone spray nozzle 520 is formed in having a rod-shape and is vertically disposed. The ozone spray nozzle 520 is provided with a plurality of spray holes 522 arranged in a longitudinal direction thereof. The ozone spray nozzle 520 has a length that is long enough to supply the ozone to all of the wafers W loaded in the boat 300.

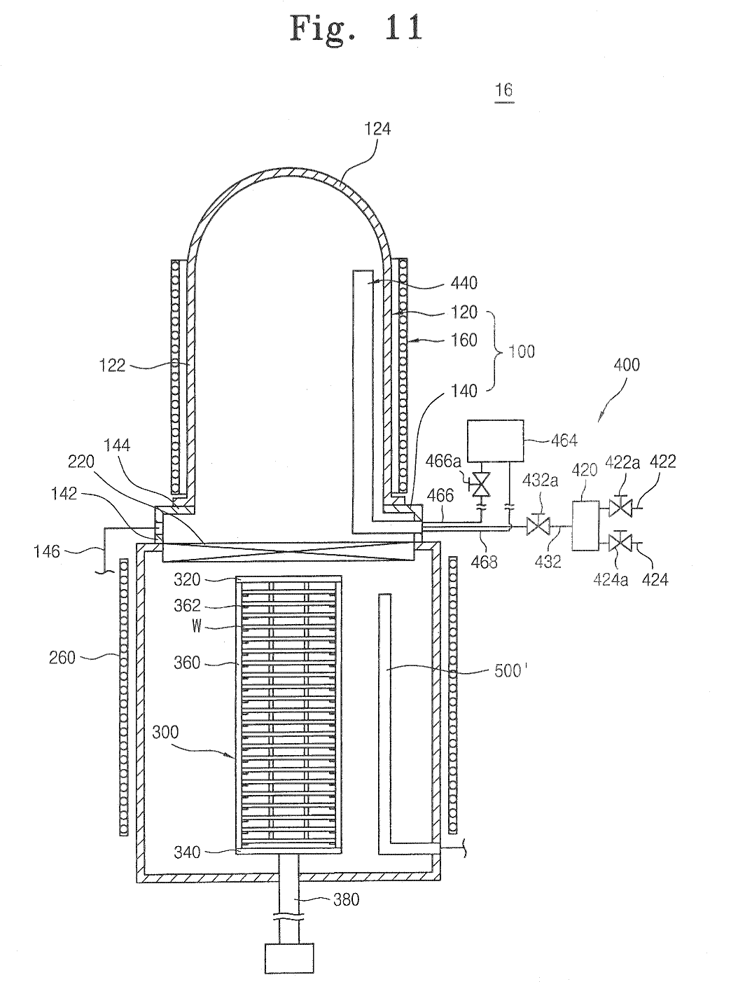

FIG. 11 is a schematic view of an oxidation treatment apparatus according to another exemplary embodiment of the present invention. According to an oxidation treatment apparatus 14 of FIG. 11, a second ozone supply unit 500′ installed on the load-lock chamber 200 and a heating member 260 for heating the load-lock chamber 200 are added to the oxidation treatment apparatus 10 of FIG. 1. The second ozone supply unit 500′ is identical in structure to the first ozone supply unit 300. The heating member 260 is disposed around the load-lock chamber 200. When the oxidation treatment apparatus 16 of FIG. 11 is used, a relatively thick passivation layer can be formed on each of the wafers W in the load-lock chamber 200.

According to exemplary embodiments of the present invention, an initial oxidation is realized for the wafers W in the load-lock chamber 200 by supplying the ozone to the load-lock chamber 200 before the wafers W move into the process chamber 100 and thus hydrocarbon is removed from the wafers W. Therefore, a high quality oxidation layer can be formed on the wafers W during the oxidation process.

The diffusion process using the above-described oxidation treatment apparatus will now be described.

The wafers W are first loaded in the boat 300 disposed in the load-lock chamber 200 and the ozone is supplied into the load-lock chamber 200 to remove the hydrocarbon from the wafers W and form the passivation layer on each wafer W. At this point, the load-lock chamber 200 may be maintained at a normal temperature of about 150° C. and a thickness of the passivation layer may be within the range of about 2 to about 10 Å. When the process is performed at a relatively high temperature, the ozone spray nozzle 440 may be cooled by the cooling member 460.

After the above, the boat 300 moves into the process chamber 100. The ozone generated from the ozone generator 420 is supplied to the ozone spray nozzle 440. At this point, cooled nitrogen gas is supplied to the cooling tube 462 provided around the ozone spray nozzle 440 to prevent the ozone in the ozone spray nozzle 440 from being decomposed.

In the above-described exemplary embodiments, an example where the apparatus treats a plurality of wafers is illustrated, the exemplary embodiments of the present invention are not limited to this example. That is, the apparatus may be designed to treat only one wafer.

According to the exemplary embodiments of the present invention, as the ozone is generated at the exterior during the oxidation process and is then supplied into the process chamber, no hydrogen or less hydrogen is implanted in the oxidation layer formed on the wafer, thereby improving the reliability of the oxidation layer.

In addition, the exterior generation of the ozone enables the process chamber to be maintained at a relatively low temperature, thereby making it possible to form a relatively thin oxidation layer on the wafer.

Furthermore, as the ozone spray nozzle disposed in the process chamber is cooled by the cooling member, the decomposition of the ozone can be prevented within the overall range of the ozone spray nozzle.

In addition, as the metal particles can be exhausted out of the process chamber by the removal gas, the reliability of the resulting oxidation layer can be improved.

Furthermore, as the hydrocarbon can be removed from the wafers in the load-lock chamber by the initial oxidation process, an oxidation layer having improved quality can be formed on the wafer by the oxidation process in the process chamber.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. An oxidation treatment apparatus for oxidizing a surface of a substrate, comprising:
a process chamber for performing a process;
a boat supporting the substrate and disposed in the process chamber during the process; and
a first ozone supply unit supplying ozone to the process chamber,
wherein the first ozone supply unit comprises:
an ozone generator disposed at an exterior of the process chamber; and an ozone spray nozzle disposed in the process chamber to spray the ozone supplied from the ozone generator into the process chamber.

2. The oxidation treatment apparatus of claim 1, wherein the first ozone supply unit further comprises a cooling member for cooling the ozone supplied to the ozone spray nozzle.

3. The oxidation treatment apparatus of claim 2, wherein the cooling member comprises a cooling tube along which coolant flows, the cooling tube being disposed to enclose the ozone spray nozzle.

4. The oxidation treatment apparatus of claim 1, further comprising a plurality of substrates vertically stacked in the boat and the ozone spray nozzle is vertically arranged and provided with a plurality of spray holes arranged in a vertical direction along a length of the ozone spray nozzle.

5. The oxidation treatment apparatus of claim 4, wherein the first ozone supply unit further comprises:
a cooling tube along which coolant flows, the cooling tube being disposed to enclose the ozone spray nozzle; and
a separation plate for dividing a space of the cooling tube into first and second compartments so that the coolant flows upward along the first compartment and then flows downward along the second compartment.

6. The oxidation treatment apparatus of claim 5, wherein the ozone spray nozzle is disposed in the cooling tube;
the cooling tube is provided with holes corresponding to the spray holes formed on the ozone spray nozzle, and
the first ozone supply unit further comprises a plurality of spray tubes inserted into the spray holes of the ozone spray nozzle and the holes of the cooling tube.

7. The oxidation treatment apparatus of claim 6, further comprising a removal gas supply tube connected to an ozone supply tube connecting the ozone spray nozzle to the ozone generator to supply a removal gas into the process chamber, the removal gas can react with metal particles in the process chamber to remove the metal particles.

8. The oxidation treatment apparatus of claim 7, wherein a volume of the removal gas supplied into the process chamber is within the range of about 1/10 to about 1/10000 of that of the ozone gas supplied into the process chamber.

9. The oxidation treatment apparatus of claim 7, wherein the removal gas includes at least one gas selected from the group consisting of trichloroethane (C₂H₃Cl₃), trichloroethylene (C₂HCl₃) and hydrogen chloride (HCl).

10. The oxidation treatment apparatus of claim 1, further comprising:
a load-lock chamber disposed below the process chamber to provide a space where the wafer is load in the boat;
a boat driving unit for moving the boat between the process chamber and the load-lock chamber; and
a second ozone supply unit supplying ozone to the load-lock chamber to form a passivation layer on the substrate loaded in the boat disposed in the load-lock chamber;
wherein the second ozone supply unit comprises:
an ozone generator disposed at an exterior of the load-lock chamber; and
an ozone spray nozzle disposed in the load-lock chamber to spray the ozone supplied from the ozone generator into the load-lock chamber.

11. The oxidation treatment apparatus of claim 10, further comprising a plurality of substrates vertically stacked in the boat and the ozone spray nozzle of the second ozone supply unit is vertically arranged and provided with a plurality of spray holes arranged in a vertical direction along a length of the ozone spray nozzle.

12. The oxidation treatment apparatus of claim 10, further comprising a heating member for heating an interior of the load-lock chamber to a process chamber.

13. The oxidation treatment apparatus of claim 12, wherein the second ozone supply unit further includes a cooling member for cooling the ozone supplied to the ozone spray nozzle disposed in the load-lock chamber.

14. An oxidation treatment method for oxidizing a surface of a substrate, comprising:
generating ozone at an exterior of a process chamber; and
supplying the ozone into the process chamber to oxidize the surface of the substrate.

15. The oxidation treatment method of claim 14, wherein the ozone is sprayed toward the substrate through an ozone spray nozzle disposed in the process chamber and the ozone in the ozone spray nozzle is cooled by coolant.

16. The oxidation treatment method of claim 15, further comprising supplying a removal gas for removing residual metal in the process chamber during the oxidation process which supplies the ozone into the process chamber.

17. The oxidation treatment method of claim 16, wherein a volume of the removal gas supplied into the process chamber is within the range of about 1/10 to about 1/10000 of that of the ozone gas supplied into the process chamber.

18. The oxidation treatment method of claim 16, wherein the removal gas comprises at least one gas selected from the group consisting of trichloroethane (C₂H₃Cl₃), trichloroethylene (C₂HCl₃) and hydrogen chloride (HCl).

19. The oxidation treatment method of claim 15, further comprising vertically stacking a plurality of substrates in the boat.

20. The oxidation treatment method of claim 14, further comprising forming a passivation layer on the substrate loaded in the boat disposed in a load-lock chamber by supplying ozone into a load-lock chamber before the process is performed in the process chamber.

21. The oxidation treatment method of claim 20, further comprising heating the substrate in the load-lock chamber while the passivation layer is formed on the substrate by ozone supplied into the load-lock chamber.

22. The oxidation treatment method of claim 14, wherein the process is for forming a tunnel oxidation layer in a flash memory.
